(19) United States
(12) Patent Application Publication
(10) Pub. No.: US 2010/0240330 A1
(43) Pub. Date: Sep. 23, 2010

(54) DIGITAL SIGNAL PROCESSING DEVICE AND RADIO COMMUNICATION APPARATUS

(75) Inventor: Toshio Fujisawa, Kanagawa (JP)

Correspondence Address: TUROCY & WATSON, LLP, 127 Public Square, 57th Floor, Key Tower, CLEVELAND, OH, 44114, US

(73) Assignee: KABUSHIKI KAISHA TOSHIBA, Tokyo (JP)

(21) Appl. No.: 12/720,997

(22) Filed: Mar. 10, 2010

(30) Foreign Application Priority Data
Mar. 18, 2009 (JP) 2009-066902

(51) Int. Cl. H03D 7/16; G06F 17/10; G06F 1/26

(52) U.S. Cl. 455/118; 455/131; 708/300; 713/300; 708/603

(57) ABSTRACT

A digital signal processing device includes: a memory for coefficient storage including partial memories that dividedly store, for each plurality of bits, a plurality of filter coefficients as divided data; a control unit that outputs, to the memory for coefficient storage, an address signal added with activation/inactivation control information; a CE-signal interrupting unit that transmits the CE signals to the partial memories or interrupts the CE signals based on the activation/inactivation control information; an output selecting unit that is provided in at least a part of the partial memories and selects and outputs, based on the activation/inactivation control information, an output of the partial memory or all-bit zero value; a multiplier that performs multiplication of each of a plurality of input data and each of the filter coefficients including the output of the output selecting unit; and an integration circuit system that integrates multiplication results output from the multiplier.

### CROSS-REFERENCE TO RELATED APPLICATIONS

This application is based upon and claims the benefit of priority from the prior Japanese Patent Application No. 2009-066902, filed on Mar. 18, 2009; the entire contents of which are incorporated herein by reference.

### BACKGROUND OF THE INVENTION

1. Field of the Invention

The present invention relates to a digital signal processing device and a radio communication apparatus.

2. Description of the Related Art

As a processor for executing high-speed filter arithmetic processing on sound data and image data, there is a digital signal processing device (a digital signal processor; DSP). In general, the DSP has a memory that stores filter coefficients (a memory for coefficient storage) separately from a memory that stores data as an arithmetic operation target (a memory for data storage). The DSP multiplies input data sequentially read out from the memory for data storage with the filter coefficients sequentially read out from the memory for coefficient storage and sequentially accumulates multiplication results in an accumulator to thereby perform a sum-of-products operation.

Arithmetic operation accuracy of the DSP depends upon bit width of data and an operator. Therefore, usually, the operator has sufficient bit width such as 32 bits. However, a general filter coefficient can be represented by, for example, a sinc function. Not all coefficient data of the filter coefficient need the 32-bit width. Specifically, even when the number of valid bits is small, power is also supplied to memory cells in which null bits are stored and data for 32 bits is always read out from the memory for coefficient storage. Therefore, there is room for power reduction because power is supplied to the null bits.

As a technology for reducing power consumption of the DSP, for example, as disclosed in Japanese Patent Application Laid-Open No. H03-262206, there is a technology for providing two address counters and two memories and, when an overflow occurs in one address counter, a coefficient value of the other address counter is adjusted by a predetermined value to enable writing of data and reduce power consumption required for the writing. As disclosed in Japanese Patent Application Laid-Open No. 2008-85923, there is a technology for executing an arithmetic operation at arithmetic operation accuracy corresponding to an execution condition for filter processing to thereby prevent useless power consumption. Further, as disclosed in Japanese Patent Application Laid-Open No. 2004-362438, there is a technology for adding a shifter to a sum-of-products circuit of a DSP to thereby reduce the number of times of an arithmetic operation. However, none of the three technologies prevents useless power consumption in the coefficient data readout.

### BRIEF SUMMARY OF THE INVENTION

A digital signal processing device according to an embodiment of the present invention comprises:

a memory for coefficient storage including partial memories that dividedly store, for each plurality of bits, as divided data, a plurality of filter coefficients having predetermined bit width and are respectively activated by chip enable (CE) signals, the memory for coefficient storage outputting the divided data of the filter coefficient corresponding to an input address signal from the partial memories, respectively;

a control unit that outputs, to the memory for coefficient storage, the address signal added with, for each of the filter coefficients, activation/inactivation control information for designating, for each of the partial memories, whether the CE signals are transmitted to the partial memories or interrupted according to whether the divided data forming the filter coefficient includes valid bits;

a CE-signal interrupting unit that transmits the CE signals to the partial memories or interrupts the CE signals based on the activation/inactivation control information;

an output selecting unit that is provided in at least a part of the partial memories and selects and outputs, based on the activation/inactivation control information, an output of the partial memory or all-bit zero value;

a multiplier that performs multiplication of each of a plurality of input data and each of the filter coefficients including the output of the output selecting unit; and

an integration circuit system that integrates multiplication results output from the multiplier.

A radio communication apparatus according to an embodiment of the present invention comprises:

a host interface unit that receives digital input data from a host device;

a digital signal processing device that executes FIR processing on the received input data;

a D/A conversion unit that D/A-converts the input data subjected to the FIR processing;

an antenna that transmits a high-frequency signal;

a high-frequency analog processing unit that modulates the D/A-converted input data into a high-frequency signal that can be transmitted via the antenna, wherein

the digital signal processing device includes:
a memory for coefficient storage including partial memories that dividedly store, for each plurality of bits, as divided data, a plurality of filter coefficients having predetermined bit width, which form a FIR filter for executing the FIR processing, and are respectively activated by chip enable (CE) signals, the memory for coefficient storage outputting the divided data of the filter coefficient corresponding to an input address signal from the partial memories, respectively;
a control unit that outputs, to the memory for coefficient storage, the address signal added with, for each of the filter coefficients, activation/inactivation control information for designating, for each of the partial memories, whether the CE signals are transmitted to the partial memories or interrupted according to whether the divided data forming the filter coefficient includes valid bits;
a CE-signal interrupting unit that transmits the CE signals to the partial memories or interrupts the CE signals based on the activation/inactivation control information;
an output selecting unit that is provided in at least a part of the partial memories and selects and outputs, based on the activation/inactivation control information, an output of the partial memory or all-bit zero value;
a multiplier that performs multiplication of each of a plurality of the input data and each of the filter coefficients including the output of the output selecting unit; and
an integration circuit system that integrates multiplication results output from the multiplier.

A radio communication apparatus according to an embodiment of the present invention comprises:

an antenna that receives a high-frequency signal;

a high-frequency analog processing unit that demodulates the high-frequency signal received by the antenna and generates analog input data;

an A/D conversion unit that A/D-converts the generated input data;

a digital signal processing device that executes FIR processing on the A/D-converted input data; and

a host interface unit that transmits the input data subjected to the FIR processing to a host device, wherein

the digital signal processing device includes:
a memory for coefficient storage including partial memories that dividedly store, for each plurality of bits, as divided data, a plurality of filter coefficients having predetermined bit width, which form a FIR filter for executing the FIR processing, and are respectively activated by chip enable (CE) signals, the memory for coefficient storage outputting the divided data of the filter coefficient corresponding to an input address signal from the partial memories, respectively;
a control unit that outputs, to the memory for coefficient storage, the address signal added with, for each of the filter coefficients, activation/inactivation control information for designating, for each of the partial memories, whether the CE signals are transmitted to the partial memories or interrupted according to whether the divided data forming the filter coefficient includes valid bits;
a CE-signal interrupting unit that transmits the CE signals to the partial memories or interrupts the CE signals based on the activation/inactivation control information;
an output selecting unit that is provided in at least a part of the partial memories and selects and outputs, based on the activation/inactivation control information, an output of the partial memory or all-bit zero value;
a multiplier that performs multiplication of each of a plurality of the input data and each of the filter coefficients including the output of the output selecting unit; and
an integration circuit system that integrates multiplication results output from the multiplier.

### BRIEF DESCRIPTION OF THE DRAWINGS

FIG. 1 is a graph for explaining an example of filter coefficients;

FIG. 2 is a diagram for explaining the configuration of a DSP according to a first embodiment of the present invention;

FIG. 3 is a diagram for explaining the configuration of a memory for coefficient storage;

FIG. 4 is a diagram for explaining an address signal;

FIG. 5 is a flowchart for explaining the operation of the DSP according to the first embodiment;

FIG. 6 is a diagram for explaining the configuration of a DSP according to a second embodiment of the present invention; and

FIG. 7 is a diagram for explaining the configuration of a radio communication apparatus including a DSP according to a third embodiment of the present invention.

### DETAILED DESCRIPTION OF THE INVENTION

Exemplary embodiments of a digital signal processing device and a radio communication apparatus according to the present invention will be explained below in detail with reference to the accompanying drawings. The present invention is not limited to the following embodiments.

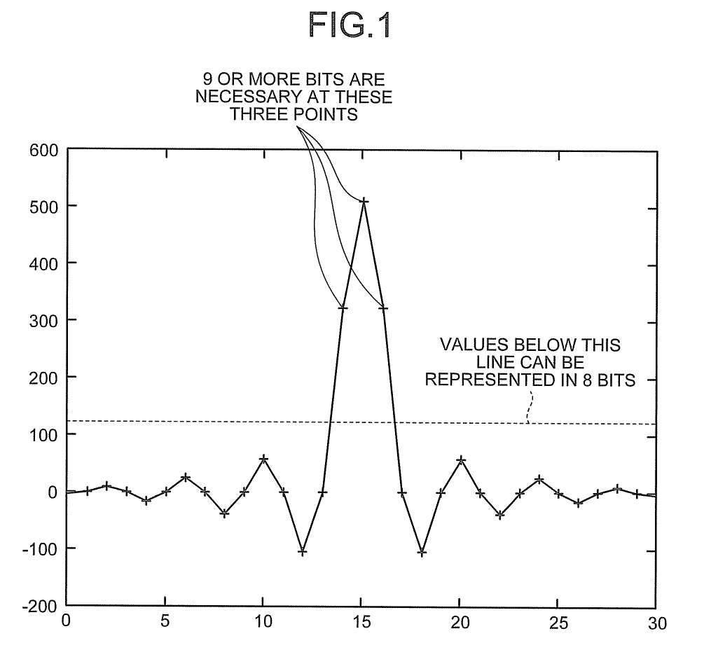

FIG. 1 is a graph for explaining a roll-off filter having a roll-off coefficient of 0.1, the number of taps of 31, and tap weight accuracy of 10 bits. As shown in the figure, a filter coefficient in a tap in the center is a maximum of 511. Specifically, a memory having 16-bit width can store filter coefficients shown in FIG. 1 including signs. Among values at thirty-one points, because values except those at three points of the maximum are equal to or smaller than 128 (=2⁷), the values including signs can be represented by the number of bits equal to or smaller than 8 bits. Therefore, when a memory having 16-bit width is prepared, concerning addresses for storing the values except those at the three points, at least high-order 8 bits are null bits. When readout of the filter coefficients is executed, because power is supplied even for the null bits to read out the filter coefficients, power consumption for the power supplied to the null bits are wasted.

As a main characteristic of a first embodiment of the present invention is that a memory for coefficient storage that stores filter coefficients is divided into plural partial memories that dividedly store the filter coefficients as divided data for each of plural bits, the partial memories that dividedly store only null bits in the filter coefficient as a readout target are not activated, and only the partial memories that dividedly store valid bits are activated to supply power to the partial memories, whereby power consumption for the power supplied to the null bits is eliminated. In the following explanation, bit width of the memory for coefficient storage is 32 bits and the number of division is two.

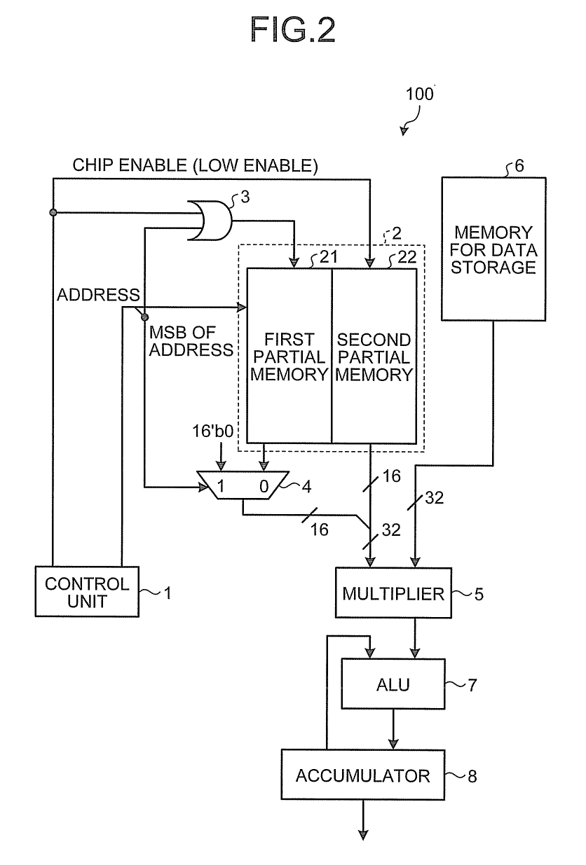

FIG. 2 is a block diagram for explaining the configuration of a DSP according to the first embodiment. As shown in the figure, a DSP 100 includes a memory for coefficient storage 2 that stores filter coefficients, an OR circuit 3 as a chip enable (CE) signal interrupting unit, and a control unit 1 that controls an address signal line and a chip enable signal line (CE line) to cause the memory for coefficient storage 2 to output the filter coefficients.

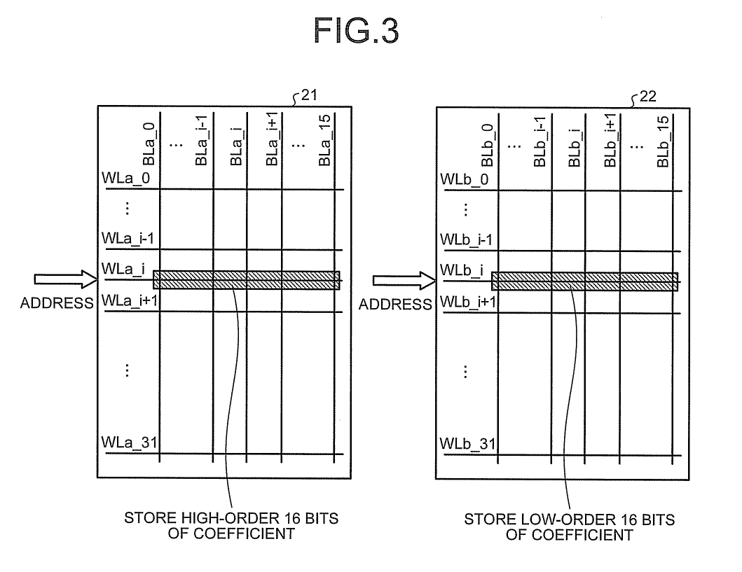

The memory for coefficient storage 2 is divided into a first partial memory 21 and a second partial memory 22. The first partial memory 21 dividedly stores high-order 16 bits of a 32-bit filter coefficient and the second partial memory 22 dividedly stores low-order 16 bits of the 32-bit filter coefficient. FIG. 3 is a diagram for explaining the configuration of the memory for coefficient storage 2. Each of the first partial memory 21 and the second partial memory 22 has plural memory cells (not shown), each of which stores a 1-bit value, arranged in a matrix shape and has, as signal lines for accessing the memory cells, word lines as address selection lines and bit lines as data readout lines. Specifically, as shown in the figure, in the first partial memory 21, thirty-two word lines (WLa_0 to WLa_31) are disposed in the lateral direction on the paper surface and sixteen bit lines (BLa_0 to BLa_15) are disposed in the longitudinal direction on the paper surface. Similarly, in the second partial memory 22, word lines (WLb_0 to WLb_31) are disposed in the lateral direction on the paper surface and bit lines (BLb_0 to BLb_15) are disposed in the longitudinal direction on the paper surface.

In a state in which both of the first partial memory 21 and the second partial memory 22 are activated, one word line is selected from the partial memory 21 and one word line is selected from the partial memory 22 by one address signal. Power is supplied to the selected word lines. The first partial memory 21 reads out 1-bit values from the respective memory cells located at cross points of the word line, to which the power is supplied, and the bit lines BLa_0 to BLa_15 and outputs a read-out value having 16 bits in total as high-order 16 bits of the filter coefficient. The second partial memory 22 reads out 1-bit values from respective memory cells located at cross points of the selected word line and the bit lines BLb_0 to BLb_15 and outputs a read-out value having 16 bits in total as low-order 16 bits of the filter coefficient. In a state in which the first partial memory 21 is not activated and the second partial memory 22 is activated, power is supplied to only the word lines of the second partial memory 22. The second partial memory 22 performs readout operation and outputs a 16-bit value as a low-order digit of the filter coefficient.

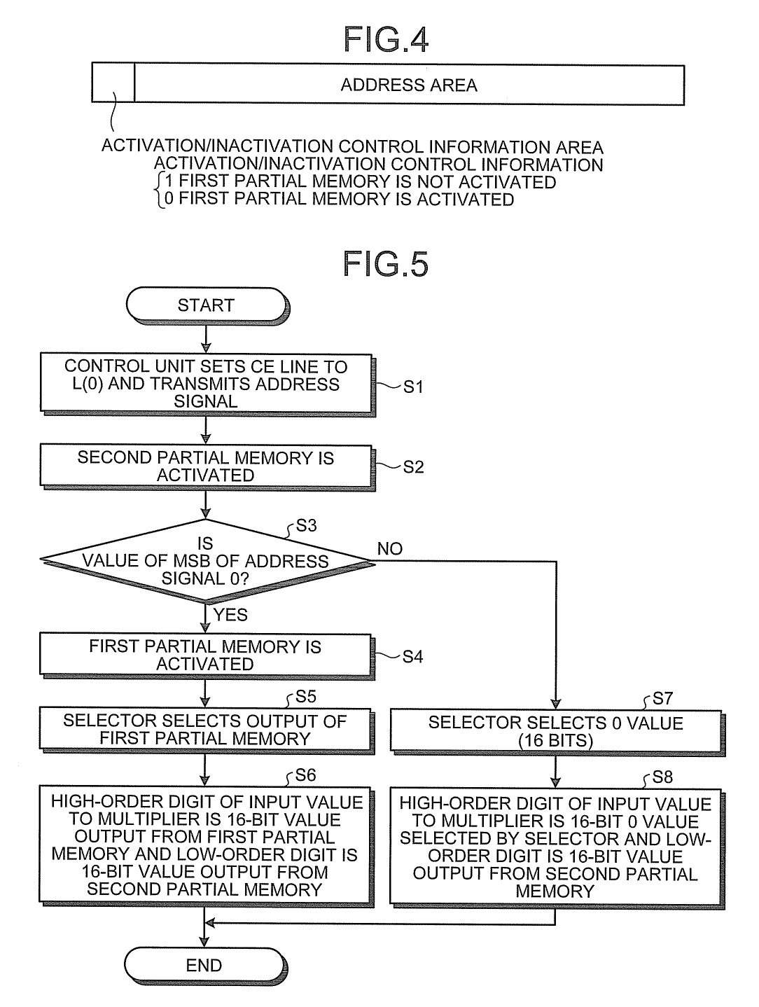

FIG. 4 is a diagram for explaining an address signal in the first embodiment. As shown in the figure, the address signal includes an address area for storing an address and an activation/inactivation control information area for storing activation/inactivation control information that is information for designating, for each of partial memories, whether a CE signal for activating the partial memories 21 and 22 is transmitted or interrupted according to whether valid bits are included in divided data forming a filter coefficient. It is assumed that the CE signal is always transmitted to the second partial memory 22 and it is designated whether the CE signal to the first partial memory 21 is transmitted or interrupted. It is assumed that a most significant bit (MSB) is the activation/inactivation control information area and, when the first partial memory 21 is activated, “0” is stored in the most significant bit and, when the first memory 21 is not activated, “1” is stored in the most significant bit. Specifically, when a high-order digit includes valid bits, the control unit 1 issues an address signal with the activation/inactivation control information set to 0 and reads out 32-bit width coefficient data including both a high-order digit and a low-order digit from the memory for coefficient storage 2. When valid bits are not included in a high-order digit, the control unit 1 issues an address signal with the activation/inactivation control information set to 1 and reads out coefficient data having low-order 16-bit width.

One end of the CE line for activating the memory for coefficient storage 2 is connected to the control unit 1. The other end of the CE line is divided into two. One of divided terminals is input to the second partial memory 22 and the other terminal is input to the OR circuit 3. One end of the address signal line is connected to the control unit 1 and the other end thereof is connected to the memory for coefficient storage 2. The address signal output from the control unit 1 is input to the first partial memory 21 and the second partial memory 22. It is assumed that the CE line is low-enabled.

The value of the MSB of the address signal as the activation/inactivation control information, i.e., the activation/inactivation control information is input to the OR circuit and a selector 4 explained later by signal lines branching from the address signal lines. The OR circuit 3 executes an OR operation based on the input CE signal issued by the control unit 1 and the input activation/inactivation control information and outputs an execution result to the first partial memory 21 as a CE signal.

The DSP 100 includes the selector 4 as an output selecting unit, a multiplier 5, a memory for data storage 6, an arithmetic logic unit (ALU) 7, and an accumulator 8. The selector 4 selects, based on the activation/inactivation control information input while branching from the address signal line, one of a 16-bit value output from the first partial memory 21 and a 16-bit substituted value. The substituted value is a 16-bit zero value. When the activation/inactivation control information is “1”, i.e., the first partial memory 21 is not activated, the selector 4 selects the substituted value. When the activation/inactivation control information is “0”, the selector 4 selects the output from the first partial memory 21. The 16-bit value selected by the selector 4 is combined with a value output from the second partial memory 22. A filter coefficient having 32 bits in total with an output value of the selector 4 set as high-order 16 bits and an output value from the second partial memory 22 set as low-order 16-bits is formed. The formed filter coefficient is input to the multiplier 5.

In the memory for data storage 6, data (32-bit input data) as a filter processing target is stored. The input data read out from the memory for data storage 6 is input to the multiplier 5. The multiplier 5 multiplies a filter coefficient and the input data together. The ALU 7 and the accumulator 8 configure an integration circuit system. Specifically, an output result from the multiplier 5 is input to the ALU 7. The ALU 7 adds up an input value and a value accumulated in the accumulator 8 and stores an arithmetic operation result in the accumulator 8. The accumulator 8 outputs an integrated value of a multiplied value of all taps to the outside as a filter operation processing result.

FIG. 5 is a flowchart for explaining operation for performing activation/inactivation control for the memory for coefficient storage 2 and inputting a filter coefficient to the multiplier 5.

As shown in the figure, first, the control unit 1 sets the CE line to 0 (low) and transmits an address signal (step S1). Then, because the control unit 1 and the second partial memory 22 are directly connected, the second partial memory 22 is activated (step S2).

Different operation is executed according to whether a value of a MSB of the address signal transmitted by the control unit 1 is “0” or “1”. When the value of the MSB of the address signal transmitted by the control unit 1 is “0” (“Yes” at step S3), “0” as a value of the CE line of the control unit 1 and “0” as the MSB value are input to the OR circuit 3. The OR circuit 3 outputs “0” as an OR operation result to the first partial memory 21 as a CE signal. As a result, the first partial memory 21 is activated (step S4). The selector 4 selects, from a substituted value and an output value of the first partial memory 21, the output value from the first partial memory 21 because the MSB value input as a selection signal is “0” (step S5). Then, a 32-bit filter coefficient with the output value from the first partial memory 21 set as a high-order digit and an output value from the second partial memory 22 set as a low-order digit is formed. The formed filter coefficient is input to the multiplier 5 (step S6). The control unit 1 ends the operation for reading out a filter coefficient from the memory for coefficient storage 2.

When the value of the MSB of the address signal transmitted by the control unit 1 is “1” (“No” at step S3), “0” as a value of the CE line of the control unit 1 and “1” as the MSB value are input to the OR circuit 3. The OR circuit 3 outputs “1” as an OR operation result to the first partial memory 21 as a CE signal. The first partial memory 21 is not activated. The selector 4 selects a substituted value of a 16-bit zero value because the MSB value input as a selection signal is “1” (step S7). Then, a 32-bit filter coefficient with the substituted value of the 16-bit zero value set as a high-order digit and an output value from the second partial memory 22 set as a low-order digit is input to the multiplier 5 (step S8). The control unit 1 ends the operation for reading out a filter coefficient from the memory for coefficient storage 2.

As explained above, in the DSP 100, the memory for coefficient storage 2 is divided into two along bit lines. When a filter coefficient not including valid bits in a high-order digit is read out, the first partial memory 21 that stores a high-order digit is not activated and a substituted value fixed to zero is output. In general, power consumption of a logic circuit that outputs the substituted value and the selector 4 that selects one of the substituted value and the output value from the first partial memory 21 is extremely small compared with power consumption during a memory access. In other words, in the DSP 100, power consumption in reading out the filter coefficient not including valid bits in a high-order digit is eliminated and power consumption for the memory access is reduced.

In the above explanation, the number of divisions of the memory for coefficient storage 2 is two. However, the number of divisions is arbitrary. For example, the memory for coefficient storage 2 can be divided into four. When the memory for coefficient storage 2 is divided into four, it is advisable to represent the activation/inactivation control information with two bits and control CE signals input to divided respective partial memories.

The selector 4 as an output selecting unit is provided in only the first partial memory 21. However, it is also possible to set information for designating whether a CE signal to the second partial memory 2 is transmitted or interrupted in the activation/inactivation control information and select, based on the information, the output from the second partial memory 22 and the substituted value.

As an example of the filter coefficient, the roll-off filter is explained. However, the first embodiment can be applied to a general digital filter other than the roll-off filter. For example, the first embodiment can be applied to a FIR filter.

In general, when input data is multiplied with coefficient data including a large number of null bits, time for the arithmetic operation is short compared with time for multiplying input data with coefficient data including a small number of null bits. As a technology for performing low power consumption control based on an arithmetic processing amount, a dynamic voltage frequency scaling (DVFS) technology is known that is a method of reducing power consumption by lowering a working frequency when the arithmetic processing amount is small and lowering a power supply voltage by a margin of working speed. However, usually, software determines timing for changing the power supply voltage according to this technology. Therefore, it is impossible to perform fine control for estimating power consumption in a unit of, for example, one clock to several clocks and changing the power supply voltage according to a result of the estimation. A second embodiment of the present invention realizes fine power supply voltage control by using activation/inactivation control information.

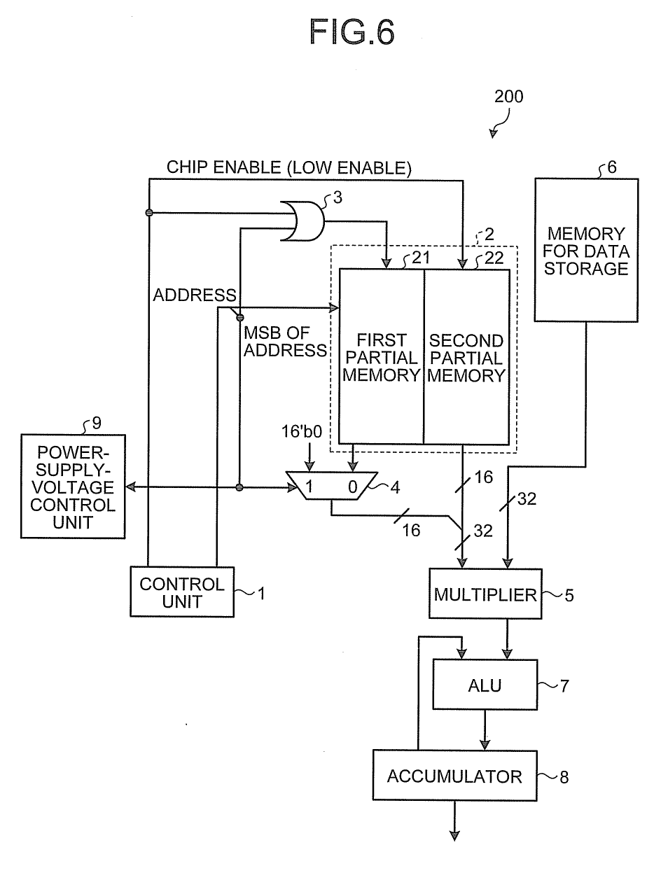

FIG. 6 is a block diagram for explaining the configuration of a DSP according to the second embodiment. Components same as those in the first embodiment are denoted by the same reference numerals and signs and detailed explanation of the components is omitted.

As shown in the figure, a DSP 200 includes, in addition to the components in the first embodiment, a power-supply-voltage control unit 9 that executes control for reducing the power supply voltage of the DSP 200 to be lower than voltage during normal operation when an arithmetic operation is performed by using a filter coefficient not including valid bits in a high-order digit. Specifically, signal lines that branch from an address signal line and transmit activation/inactivation control information are input to the power-supply-voltage control unit 9. When the activation/inactivation control information is “1”, i.e., when the first partial memory 21 is not activated, the power-supply-voltage control unit 9 sets the working voltage of the DSP 200 to a power supply voltage lower than a power supply voltage during normal operation. When the activation/inactivation control information is “0”, the power-supply-voltage control unit 9 supplies the power supply voltage during the normal operation.

In general, in the memories 2 and 6, a speed degradation during low power supply voltage drop is large compared with logic circuits (components other than the memories 2 and 6 of the DSP 200). Therefore, it is desirable to separate a power supply circuit for the other logic circuits (i.e., any one of the multiplier 5 and an integration circuit system or both) from a power supply circuit for the memories 2 and 6. Specifically, it is advisable to add a voltage level shifter between the memories 2 and 6 and the logic circuits and, without changing the power supply voltage of the memories 2 and 6 (or while reducing an amount of change of the power supply voltage), substantially lower the power supply voltage of the logic circuits in a range in which the logic circuits do not malfunction.

When the power supply voltage is raised or lowered, a charge or discharge current corresponding to capacitance of the circuits flows according to the change in the power supply voltage. Therefore, when the power supply voltage is frequently changed, an increase in power consumption is caused to the contrary. However, in general, a filter coefficient has a characteristic that a value thereof gradually decreases (or increases) according to an increase of addresses. Therefore, in the second embodiment in which a section for storing a filter coefficient on a high-order digit side is activated or inactivated and the power supply voltage is changed, the power supply voltage is not frequency changed (e.g., every time one filter coefficient is read out). In other words, it is possible to realize lower power consumption according to the second embodiment.

As explained above, in the second embodiment, the power supply voltage is controlled based on the activation/inactivation control information. Therefore, because the power supply voltage is controlled for each address signal output by the control unit 1, it is possible to finely control the power supply voltage and increase an amount of reduction of power consumption compared with the system for estimating a processing amount and controlling the power supply voltage with the software.

In the above explanation, the number of divisions of the memory for coefficient storage 2 is two. However, the number of divisions can be three or more. When the number of divisions is three or more, the power-supply-voltage control unit 9 desirably changes the power supply voltage according to the number of partial memories to be activated.

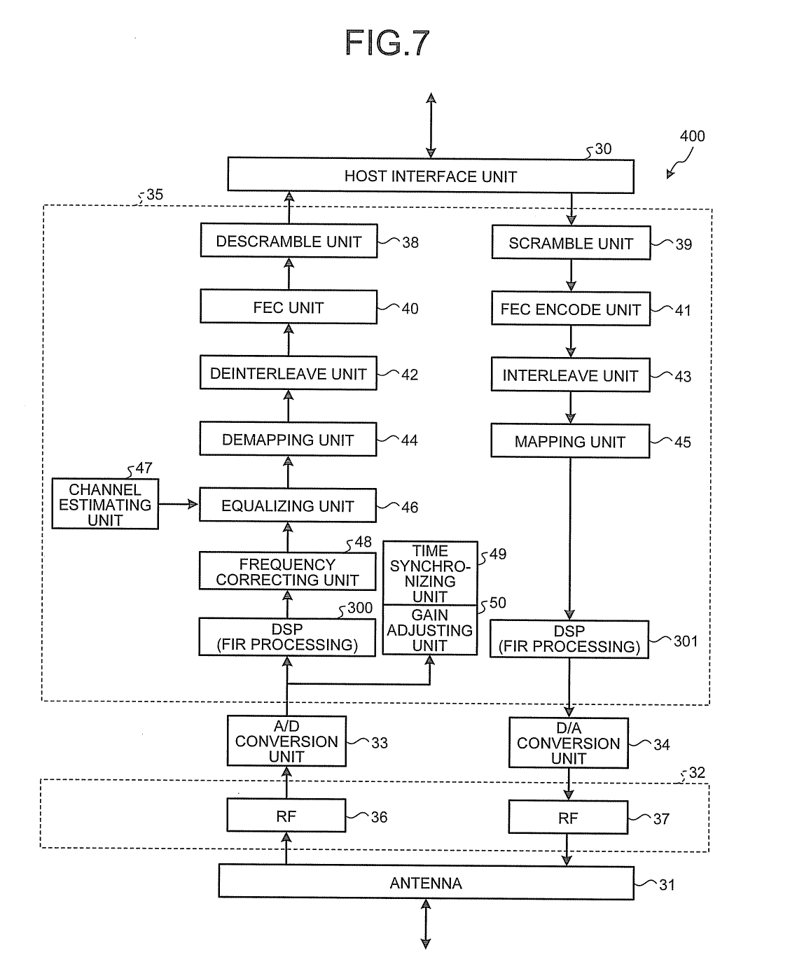

FIG. 7 is a diagram for explaining the configuration of a radio communication apparatus 400 mounted with DSPs 300 and 301 according to a third embodiment of the present invention. The radio communication apparatus 400 includes a host interface unit 30, an antenna 31 for radio communication, a harmonic-analog processing unit 32, an analog-to-digital (A/D) conversion unit 33, a digital-to-analog (D/A) conversion unit 34, and a baseband processing unit 35.

The antenna 31 transmits and receives a carrier wave (a high-frequency signal) having a predetermined harmonic.

The harmonic-analog processing unit 32 includes a RF 36 on a reception side and a RF 37 on a transmission side. The RF 36 on the reception side down-converts (demodulates) the carrier wave received by the antenna 31 and generates a predetermined analog signal. The generated analog signal is A/D-converted by the A/D conversion unit 33. A digital signal generated by the conversion is input to the baseband processing unit 35.

The host interface unit 30 is an interface for communication between a host device such as a central processing unit (CPU) and the baseband processing unit 35.

The baseband processing unit 35 executes various kinds of digital processing on the digital signal input from the A/D conversion unit 33. The digital signal after the digital processing is transmitted to the host device via the host interface unit 30. When the digital signal is received from the host device via the host interface unit 30, the baseband processing unit 35 executes the digital processing on the transmitting digital signal. The digital signal from the host device subjected to the digital processing by the baseband processing unit 35 is input to the D/A conversion unit 34 and D/A-converted. An analog signal generated by the conversion is input to the RF 37 on the transmission side included in the harmonic-analog processing unit 32. The RF 37 on the transmission side modulates the input digital signal into a predetermined high-frequency wave. The modulated high-frequency wave is transmitted from the antenna 31.

The baseband processing unit 35 includes, as components for executing the various kinds of digital processing, the DSPs 300 and 301, a descramble unit 38, a scramble unit 39, a forward error collection (FEC) unit 40, a FEC encode unit 41, a deinterleave unit 42, an interleave unit 43, a demapping unit 44, a mapping unit 45, an equalizing unit 46, a channel estimating unit 47, a frequency correcting unit 48, a time synchronizing unit 49, and a gain adjusting unit 50.

The DSPs 300 and 301 have configuration equivalent to that of the DSP 100 according to the first embodiment or the DSP 200 according to the second embodiment. The DSPs 300 and 301 execute FIR filter processing (hereinafter simply referred to as FIR processing). The first partial memory 21 dividedly stores high-order 16 bits in a 32-bit filter coefficient for executing the FIR processing. The second partial memory 22 dividedly stores low-order digit 16 bits in the filter coefficient. Functions of components of the baseband processing unit 35 including the DSPs 300 and 301 are explained below.

The scramble unit 39 executes scramble processing, which replaces digital signal input to the baseband processing unit 35 into other bit strings with low probability of occurrence of the same sequence.

The FEC encode unit 41 applies error-correctable encoding to the digital signal, and adds a redundancy bit to the strings. The interleave unit 43 executes, on the encoded digital signal, interleave processing for interchanging the bit strings such that adjacent bits are arranged in sub-carriers apart from each other.

The mapping unit 45 executes, on the digital signal subjected to the interleave processing, mapping processing for modulating the bit strings into a sub-carrier. The mapping processing can be, for example, QAM encoding.

The DSP 301 executes FIR processing on the digital signal subjected to the mapping processing. The digital signal subjected to the FIR processing is input to the D/A conversion unit 34.

The DSP 300 executes the FIR processing on the digital signal input to the baseband processing unit 35 from the A/D conversion unit 33.

The digital signal input to the baseband processing unit 35 from the A/D conversion unit 33 is also input to the time synchronizing unit 49 and the gain adjusting unit 50. The time synchronizing unit 49 detects the head of a reception frame from the digital signal, keeps the head of the reception frame, and adjusts reception processing timing after that. The gain adjusting unit 50 executes, for processing of a reception signal (the received digital signal), processing for adjusting a level of the reception signal to a predetermined level.

The frequency correcting unit 48 detects a carrier frequency error from the digital signal after the FIR processing by the DSP 300, corrects the carrier frequency error, and eliminates influence due to the frequency error.

The channel estimating unit 47 estimates distortion of phases and amplitudes of sub-carrier signals. The equalizing unit 46 removes, using distortion of a transmission channel estimated by the channel estimating unit 47, transmission channel distortion from the digital signal from which the influence due to the frequency error is removed by the frequency correcting unit 48.

The demapping unit 44 executes, on the digital signal from which the transmission channel distortion is removed, demapping processing as processing opposite to the mapping processing and restores the bit strings. The deinterleave unit 42 executes, on the digital signal subjected to the demapping processing, deinterleave processing as processing opposite to the interleave processing and restores the interchanged bit strings.

The FEC unit 40 executes error correction based on a code included in the digital signal after the deinterleave processing. The descramble unit 38 executes, on the digital signal subjected to the error correction, descramble processing for restoring the bit strings rearranged by the scramble processing to the original bit strings. The digital signal subjected to the descramble processing is transmitted to the host device via the host interface unit 30.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A digital signal processing device comprising:
a memory for coefficient storage including partial memories that dividedly store, for each plurality of bits, as divided data, a plurality of filter coefficients having predetermined bit width and are respectively activated by chip enable (CE) signals, the memory for coefficient storage outputting the divided data of the filter coefficient corresponding to an input address signal from the partial memories, respectively;
a control unit that outputs, to the memory for coefficient storage, the address signal added with, for each of the filter coefficients, activation/inactivation control information for designating, for each of the partial memories, whether the CE signals are transmitted to the partial memories or interrupted according to whether the divided data forming the filter coefficient includes valid bits;
a CE-signal interrupting unit that transmits the CE signals to the partial memories or interrupts the CE signals based on the activation/inactivation control information;
an output selecting unit that is provided in at least a part of the partial memories and selects and outputs, based on the activation/inactivation control information, an output of the partial memory or all-bit zero value;
a multiplier that performs multiplication of each of a plurality of input data and each of the filter coefficients including the output of the output selecting unit; and
an integration circuit system that integrates multiplication results output from the multiplier.

2. The digital signal processing device according to claim 1, further comprising a power-supply-voltage control unit that controls a power supply voltage based on the activation/inactivation control information.

3. The digital signal processing device according to claim 2, wherein the power supply voltage as a control target of the power-supply-voltage control unit is a power supply voltage for driving any one of the multiplier and the integration circuit system or both.

4. The digital signal processing device according to claim 1, wherein the memory for coefficient storage is divided into a plurality of partial memories along bit lines.

5. The digital signal processing device according to claim 2, wherein the memory for coefficient storage is divided into a plurality of partial memories along bit lines.

6. The digital signal processing device according to claim 3, wherein the memory for coefficient storage is divided into a plurality of partial memories along bit lines.

7. The digital signal processing device according to claim 1, wherein the filter coefficients form one of a roll-off filter and a FIR filter.

8. The digital signal processing device according to claim 2, wherein the filter coefficients form one of a roll-off filter and a FIR filter.

9. The digital signal processing device according to claim 3, wherein the filter coefficients form one of a roll-off filter and a FIR filter.

10. The digital signal processing device according to claim 1, wherein the activation/inactivation control information is added to a head of the address signal.

11. The digital signal processing device according to claim 2, wherein the activation/inactivation control information is added to a head of the address signal.

12. The digital signal processing device according to claim 3, wherein the activation/inactivation control information is added to a head of the address signal.

13. A radio communication apparatus comprising:
a host interface unit that receives digital input data from a host device;
a digital signal processing device that executes FIR processing on the received input data;
a D/A conversion unit that D/A-converts the input data subjected to the FIR processing;
an antenna that transmits a high-frequency signal;
a high-frequency analog processing unit that modulates the D/A-converted input data into a high-frequency signal that can be transmitted via the antenna, wherein
the digital signal processing device includes:
a memory for coefficient storage including partial memories that dividedly store, for each plurality of bits, as divided data, a plurality of filter coefficients having predetermined bit width, which form a FIR filter for executing the FIR processing, and are respectively activated by chip enable (CE) signals, the memory for coefficient storage outputting the divided data of the filter coefficient corresponding to an input address signal from the partial memories, respectively;
a control unit that outputs, to the memory for coefficient storage, the address signal added with, for each of the filter coefficients, activation/inactivation control information for designating, for each of the partial memories, whether the CE signals are transmitted to the partial memories or interrupted according to whether the divided data forming the filter coefficient includes valid bits;
a CE-signal interrupting unit that transmits the CE signals to the partial memories or interrupts the CE signals based on the activation/inactivation control information;
an output selecting unit that is provided in at least a part of the partial memories and selects and outputs, based on the activation/inactivation control information, an output of the partial memory or all-bit zero value;
a multiplier that performs multiplication of each of a plurality of the input data and each of the filter coefficients including the output of the output selecting unit; and
an integration circuit system that integrates multiplication results output from the multiplier.

14. The radio communication apparatus according to claim 13, wherein the digital signal processing device further includes a power-supply-voltage control unit that controls a power supply voltage based on the activation/inactivation control information.

15. The radio communication apparatus according to claim 14, wherein the power supply voltage as a control target of the power-supply-voltage control unit is a power supply voltage for driving any one of the multiplier and the integration circuit system or both.

16. The radio communication apparatus according to claim 13, wherein the memory for coefficient storage is divided into a plurality of partial memories along bit lines.

17. A radio communication apparatus comprising:
an antenna that receives a high-frequency signal;
a high-frequency analog processing unit that demodulates the high-frequency signal received by the antenna and generates analog input data;
an A/D conversion unit that A/D-converts the generated input data;
a digital signal processing device that executes FIR processing on the A/D-converted input data; and
a host interface unit that transmits the input data subjected to the FIR processing to a host device, wherein
the digital signal processing device includes:
a memory for coefficient storage including partial memories that dividedly store, for each plurality of bits, as divided data, a plurality of filter coefficients having predetermined bit width, which form a FIR filter for executing the FIR processing, and are respectively activated by chip enable (CE) signals, the memory for coefficient storage outputting the divided data of the filter coefficient corresponding to an input address signal from the partial memories, respectively;
a control unit that outputs, to the memory for coefficient storage, the address signal added with, for each of the filter coefficients, activation/inactivation control information for designating, for each of the partial memories, whether the CE signals are transmitted to the partial memories or interrupted according to whether the divided data forming the filter coefficient includes valid bits;
a CE-signal interrupting unit that transmits the CE signals to the partial memories or interrupts the CE signals based on the activation/inactivation control information;
an output selecting unit that is provided in at least a part of the partial memories and selects and outputs, based on the activation/inactivation control information, an output of the partial memory or all-bit zero value;
a multiplier that performs multiplication of each of a plurality of the input data and each of the filter coefficients including the output of the output selecting unit; and
an integration circuit system that integrates multiplication results output from the multiplier.

18. The radio communication apparatus according to claim 17, wherein the digital signal processing device further includes a power-supply-voltage control unit that controls a power supply voltage based on the activation/inactivation control information.

19. The radio communication apparatus according to claim 18, wherein the power supply voltage as a control target of the power-supply-voltage control unit is a power supply voltage for driving any one of the multiplier and the integration circuit system or both.

20. The radio communication apparatus according to claim 17, wherein the memory for coefficient storage is divided into a plurality of partial memories along bit lines.
